(19) United States
(12) Patent Application Publication
(10) Pub. No.: US 2005/0018258 A1
(43) Pub. Date: Jan. 27, 2005

(54) Image processing apparatus, image processing method, and computer product

(76) Inventors: Noriko Miyagi, Kanagawa (JP); Hirohisa Inamoto, Kanagawa (JP); Hiroyuki Shibaki, Tokyo (JP)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/898,072

(22) Filed: Jul. 23, 2004

(30) Foreign Application Priority Data
Jul. 24, 2003 (JP) 2003-201166
Jun. 11, 2004 (JP) 2004-174653

(51) Int. Cl. G06F 15/00; G03F 3/08

(52) U.S. Cl. 358/521; 358/1.9; 358/518

(57) ABSTRACT

An image processing apparatus includes an input unit that inputs an image signal created by optically scanning a document, a first filtering unit that performs a first filtering process on the image signal input to reduce degradation of image quality caused by optical scanning of the document, a compressing unit that irreversibly compresses the image signal filtered, a storage unit that stores the image signal compressed, an expanding unit that expands compressed image signal stored in the storage unit; and a second filtering unit that performs a second filtering process on the image signal expanded to reduce degradation image quality caused by compression of the image signal.

The present application claims priority to the corresponding Japanese Application Nos. 2003-201166, filed on Jul. 24, 2003 and 2004-174653, filed on Jun. 11, 2004, the entire contents of which are hereby incorporated by reference.

### BACKGROUND OF THE INVENTION

1. Field of the Invention

The present invention relates to a method, an apparatus, and a computer product for processing an image optically scanned from a document.

2. Description of the Related Art

Recently, image processing apparatuses having various functions, such as a scanner function, a photocopier function, and a printer function, are used widely. Such image processing apparatuses also have a function of temporarily storing image data scanned by a scanner in a memory to achieve fast copying or to use images in various applications including using the images in an external device.

The image processing apparatus with a function of temporarily storing the image data in the memory generally performs an irreversible compression, such as joint photographic experts group (JPEG), on image data scanned by a scanner and temporarily stores compressed image data in the memory to suppress memory resources required.

When the compressed image data is expanded and an image is output based on the expanded image data, the image quality is degraded. Therefore, an image processing apparatus with a function of suppressing the degradation of image quality caused by the irreversible compression is proposed in, for example, Japanese Patent Application Laid-Open No. 2001-309183.

The image processing apparatus described in this publication performs compression after performing a smoothing process on image data scanned by a scanner. After expanding the compressed image data, the image processing apparatus performs an edge enhancing process and performs printing of the image. The image data is processed in the order of “smoothing,” “compression,” “expansion” and “edge enhancing filtering.”

Execution of the smoothing process on image data before compression suppresses image deformation, such as mosquito noise, which is caused by degradation of a high-frequency component in later compression. Execution of the edge enhancement on expanded image data restores the sharpness of edges that was lost by compression, thereby suppressing image degradation.

In these days, the image data scanned by the scanner of an image processing apparatus is often used by an external device. For example, image data scanned by the scanner of a copying machine is stored in a memory (such as a hard disk) installed in the copying machine and the image data stored in the memory is fetched to a personal computer (PC) through a local area network (LAN) and displayed on a display.

When image data compressed and stored in a memory is read from the memory and used by the external device, the technique described above uses degraded images in many cases. The technique described above performs a smoothing process on image data scanned by a scanner, compresses the image data, and stores the image data in a memory. When the image data stored in the memory is read out and fetched to the external device, therefore, images more smudgy than the original images scanned by the scanner are displayed. Particularly, when the image data represents characters, it may become difficult to even identify the characters depending on the size of the characters.

### SUMMARY OF THE INVENTION

An image processing apparatus, image processing method, and computer product are described. In one embodiment, the image processing apparatus comprises an input unit that inputs an image signal created by optically scanning a document, a first filtering unit that performs a first filtering process on the image signal input by the input unit to reduce degradation of image quality caused by optical scanning of the document, a compressing unit that irreversibly compresses the image signal filtered by the first filtering unit, a storage unit that stores the image signal compressed by the compressing unit, an expanding unit that expands compressed image signal stored in the storage unit, and a second filtering unit that performs a second filtering process on the image signal expanded by the expanding unit to reduce degradation image quality caused by compression of the image signal.

### BRIEF DESCRIPTION OF THE DRAWINGS

FIG. 1 is a block diagram of an image processing apparatus according to one embodiment of the present invention;

FIG. 2 is a block diagram of an example of an edge detector in the image processing apparatus according to one embodiment;

FIGS. 3A to 3D are schematics of examples of four edge detecting filters in the edge detector;

FIG. 4 is a block diagram of a first filtering unit in the image processing apparatus according to one embodiment;

FIG. 5 is a schematic of an example a filter of a smoothing unit in the first filtering unit;

FIG. 6 is a block diagram of an edge enhancing unit in the first filtering unit;

FIG. 7 is a graph of characteristics of a look-up table (LUT) in an LUT converter in the edge enhancing unit;

FIG. 8 is a schematic of an example of a Laplacian filter in the edge enhancing unit;

FIG. 9 is a block diagram of a second filtering unit in the image processing apparatus according to one embodiment;

FIG. 10 is a schematic of an example of an edge enhancing filter included in the edge enhancing unit of the second filtering unit;

FIG. 11 is a block diagram of an image processing apparatus according to another embodiment of the present invention;

FIGS. 12A to 12D are schematics of examples of an edge detecting filter of an edge detector in the image processing apparatus according to one embodiment; and

FIG. 13 is a schematic of an example of a filter when a filtering unit in the image processing apparatus according to one embodiment performs edge enhancement on an image signal before compression.

### DETAILED DESCRIPTION

In one embodiment of the present invention, at least the above problems are solved in the conventional technology.

The image processing apparatus according to one embodiment of the present invention includes an input unit that inputs an image signal created by optically scanning a document; a first filtering unit that performs a first filtering process on the image signal input by the input unit to reduce degradation of image quality caused by optical scanning of the document; a compressing unit that irreversibly compresses the image signal filtered by the first filtering unit; a storage unit that stores the image signal compressed by the compressing unit; an expanding unit that expands compressed image signal stored in the storage unit; and a second filtering unit that performs a second filtering process on the image signal expanded by the expanding unit to reduce degradation image quality caused by compression of the image signal.

The image processing apparatus according to another embodiment of the present invention includes an input unit that inputs an image signal created by optically scanning a document; a filtering unit that performs a filtering process on the image signal; a compressing unit that irreversibly compresses the image signal input by the input unit; a storage unit that stores the image signal compressed by the compressing unit; an expanding unit that expands the image signal stored in the storage unit; and a determining unit that determines contents of the filtering process. Before compression of the image signal, the filtering process is used to reduce degradation of image quality caused by optical scanning of the document, and after expanding the compressed image signal, the filtering process is used to reduce degradation of image quality caused by compression of the image signal.

The image processing method according to still another embodiment of the present invention includes inputting an image signal created by optically scanning a document; performing a first filtering process on the image signal input by the input unit to reduce degradation of image quality caused by optical scanning of the document; compressing the image signal filtered by the first filtering unit; storing the image signal compressed by the compressing unit; expanding compressed image signal stored in the storage unit; and performing a second filtering process on the image signal expanded by the expanding unit to reduce degradation image quality caused by compression of the image signal.

The computer readable recording medium according to still another embodiment of the present invention stores a computer program that realizes the image processing method according to the above embodiment on a computer.

The other embodiments, features, and advantages of the present invention are specifically set forth in or will become apparent from the following detailed description of the invention when read in conjunction with the accompanying drawings.

Exemplary embodiments of an image processing apparatus, an image processing method, and a computer product according to one embodiment of the present invention will be described in detail below with reference to the accompanying drawings.

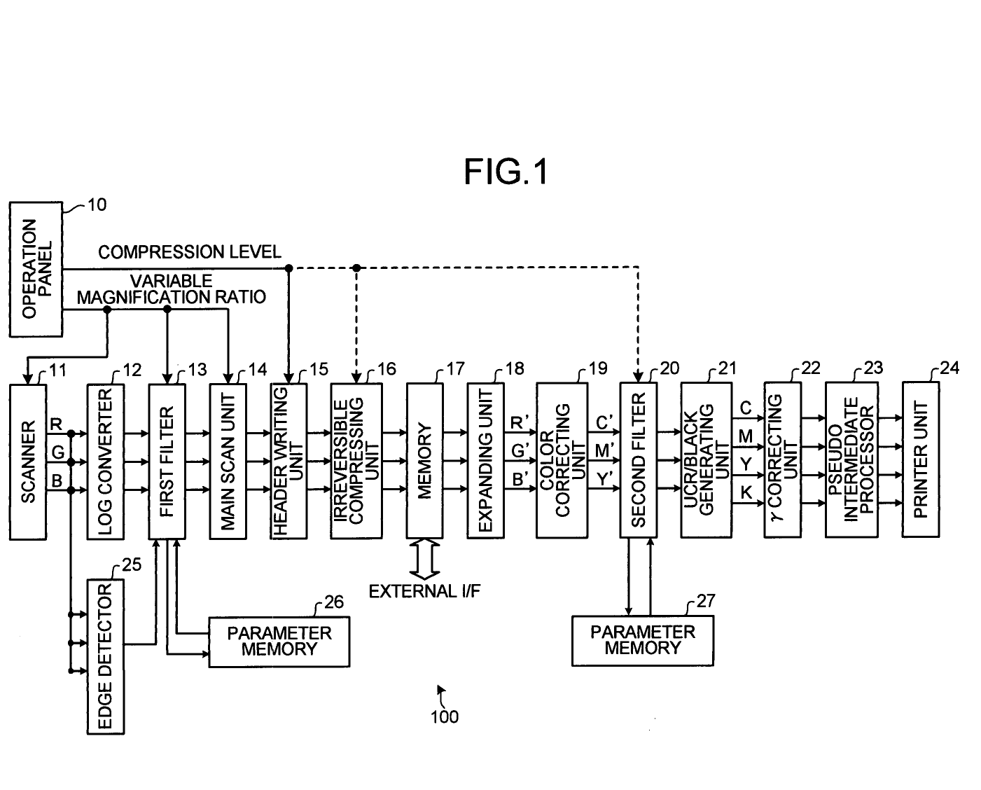

FIG. 1 is a block diagram of an image processing apparatus according to one embodiment of the present invention. An image processing apparatus 100 has an operation panel 10, a scanner 11, an LOG converter 12, a first filtering unit 13, a main scan unit 14, a header writing unit 15, an irreversible compressing unit 16, a memory 17, an expanding unit 18, a color correcting unit 19, a second filtering unit 20, a UCR (under color removal)/black generating unit 21, a y correcting unit 22, a pseudo intermediate processor 23, a printer unit 24, an edge detector 25, and parameter memories 26 and 27.

The operation panel 10 is used by a user to input various kinds of instructions to the image processing apparatus 100, and outputs an instruction signal according to the contents of the user's operation. With the use of the image processing apparatus 100 according to this embodiment, the user can instruct, for example, the variable magnification ratio of an image, and the level of the compression rate of image data at the time of storing the image data in the memory 17 by adequately operating the operation panel 10.

The scanner 11 optically scans a document placed at a predetermined position or a document fed by an automatic document feeder or the like, and generates an image signal corresponding to the scanned document. While the scanner 11 is a color scanner and generates an RGB (red, green, and blue) signal corresponding to a scanned image in this embodiment, it may of course be a monochromatic scanner.

At the time of scanning a document, the scanner 11 controls the document scan speed according to the variable magnification ratio input through the operation panel 10. More specifically, the moving speed of a carriage having a line sensor and an irradiation unit is controlled according to the variable magnification ratio when scanning a document placed at a predetermined position, whereas when scanning a document that is fed by an automatic document feeder, the feeding speed is controlled according to the variable magnification ratio. An image signal magnified at the instructed variable magnification ratio in the sub scan direction can be acquired by controlling the document scan speed. In this embodiment, the scanner 11 is incorporated in the image processing apparatus 100 and serves as an input unit to input an image signal. When the image processing apparatus does not incorporate the scanner 11, however, the image processing apparatus should be provided with an input interface that fetches an image signal, generated by an external scanner, through communication means such as a cable or near-field communication.

The scanner 11 sends the image signal, generated by scanning a document, to the LOG converter 12 and the edge detector 25.

The LOG converter 12 performs LOG conversion on the RGB image signal supplied from the scanner 11 to convert an image signal that is linear to the reflectance to an image signal that is linear to the density.

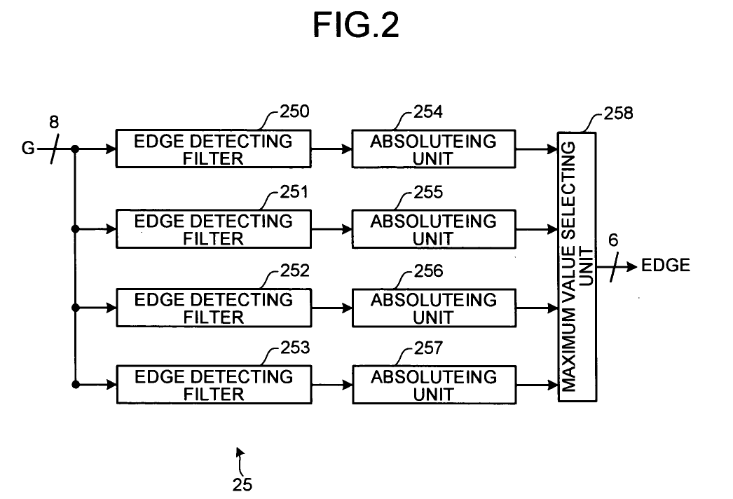

The edge detector 25 detects the edge portion in an image corresponding to the image signal supplied from the scanner 11 from the image signal. As shown in FIG. 2, the edge detector 25 in this embodiment has four edge detecting filters 250, 251, 252, and 253, four absolutization units 254, 255, 256, and 257 provided in association with the four edge detecting filters, and a maximum value selecting unit 258.

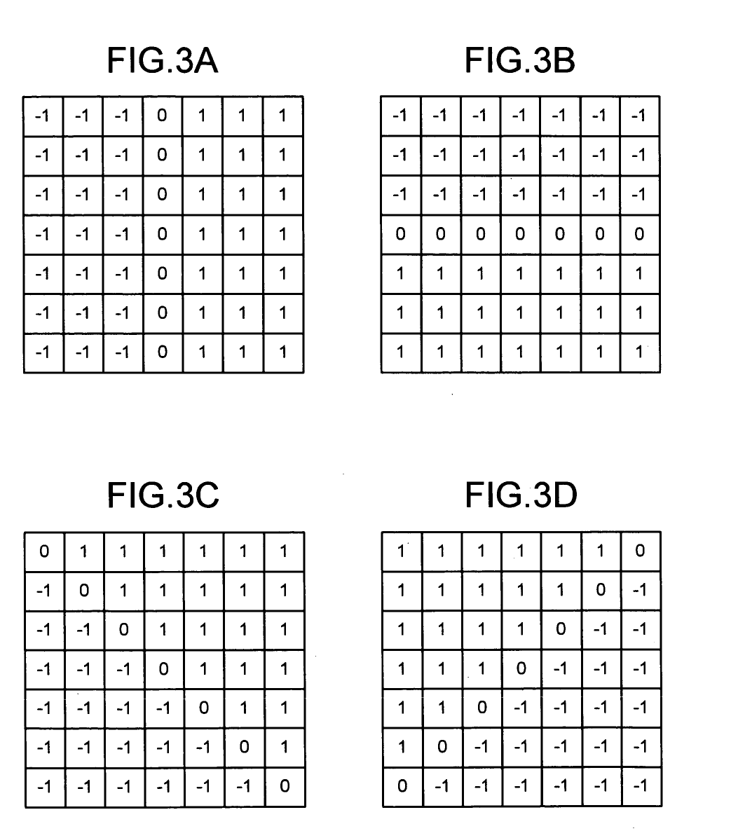

Each of the edge detecting filters 250 to 253 is supplied with an image signal (G) from the scanner 11. As the edge detecting filters 250 to 253, 7×7 filters (a) to (d) as exemplified in FIGS. 3A to 3D can be used to perform masking process.

The absolutization units 254 to 257 are supplied with output values of the four edge detecting filters 250 to 253, respectively. The absolutization units 254 to 257 send the absolute values of the output values of the associated edge detecting filters 250 to 253 to the maximum value selecting unit 258.

The maximum value selecting unit 258 selects the maximum value in the four absolute values supplied from the four absolutization units 254 to 257 and outputs a 6-bit signal indicating the selected maximum value. In this case, when the maximum value to be output is equal to or greater than 2 to the power of 6 or 64, the maximum value is rounded off to 63 when being output. The 6-bit signal is output for matching in a process at the subsequent stage (conversion by a LUT). Therefore, a signal other than a 6-bit signal may be used. In this embodiment, however, the rounding process is performed to restrict the number of bits of a signal that represents the amount of an edge detected, thereby reducing the processing burden or the like.

Although only a G signal in an RGB signal is supplied to each of the edge detecting filters 250 to 253 in FIG. 2, this signal supply is not restrictive. For example, a combined signal representing the average value or the like of an RGB signal may be supplied instead.

The output value detected by the edge detector 25 with the configuration described above is output to the first filtering unit 13.

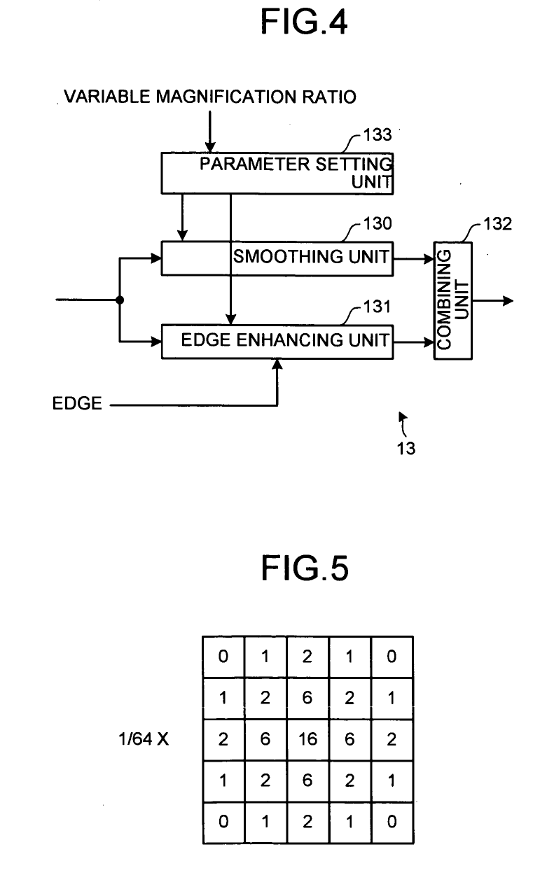

The first filtering unit 13 performs a filtering process to reduce the degradation of an image signal generated by an optical scan unit, such as the scanner 11. More specifically, the first filtering unit 13 performs a filtering process to suppress moire by pressing rolling at a dot portion while enhancing the sharpness of a character portion in an image based on the output signal of the edge detector 25 or the result of edge detection. FIG. 4 depicts an example of the first filtering unit 13.

The first filtering unit 13 has a smoothing unit 130, an edge enhancing unit 131, a combining unit 132, and a parameter setting unit 133.

The image signal supplied to the first filtering unit 13 from the LOG converter 12 is supplied to the smoothing unit 130. A 5×5 filter as shown in FIG. 5 can be used as the smoothing unit 130. The image signal supplied from the LOG converter 12 is filtered by the filter and is then sent to the combining unit 132.

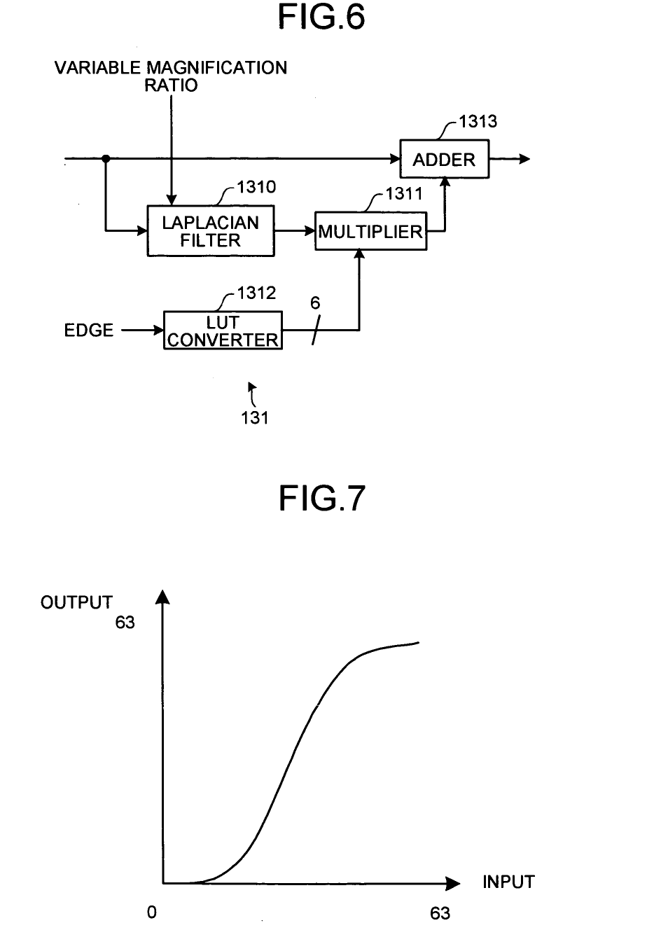

The image signal supplied to the first filtering unit 13 from the LOG converter 12 is also supplied to the edge enhancing unit 131. FIG. 6 is a block diagram of an edge enhancing unit in the first filtering unit 131. As shown in the diagram, the edge enhancing unit 131 has a Laplacian filter 1310, a multiplier 1311, an LUT converter 1312, and an adder 1313.

The LUT converter 1312 is supplied with the result of detection performed by the edge detector 25. The LUT converter 1312 has an LUT as shown in FIG. 7, and sends an output value corresponding to an input value supplied from the edge detector 25 (edge detection result) to the multiplier 1311. In this embodiment, as shown in FIG. 7, of the edge detection results represented by 6 bits, the one that has a small value is converted to zero to correct noise or the edge detection result at large number of dot lines to zero, and the one that has a large value is converted and corrected to a value close to the maximum value of 63, therefore edge enhancement can be performed adequately even at thin lines or the like.

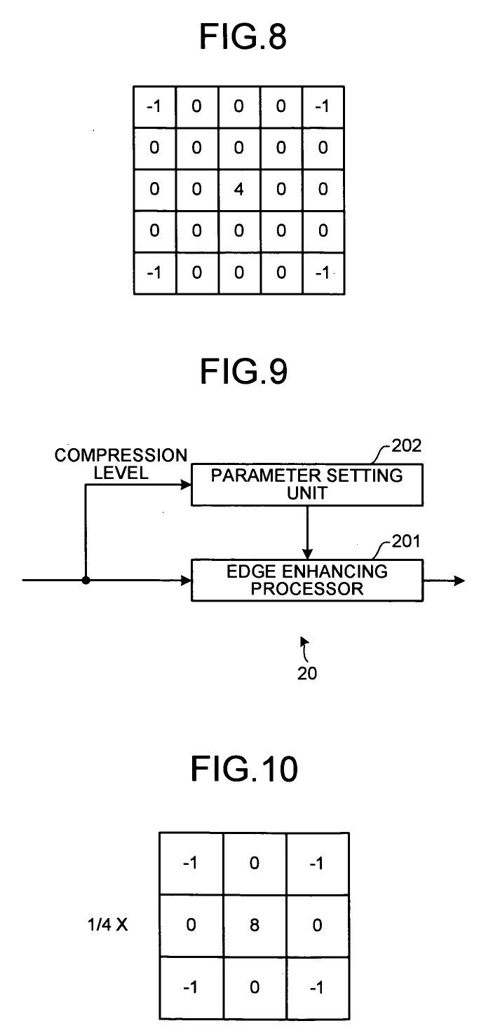

A 5×5 filter as shown in FIG. 8 is used as the Laplacian filter 1310 in this embodiment. The image signal from the LOG converter 12 is supplied to the Laplacian filter 1310 in order to be filtered and is output to the multiplier 1311.

The multiplier 1311 is supplied with the output value from the LUT converter 1312 and the image signal filtered by the Laplacian filter 1310 and multiplies the inputs.

The multiplication result from the multiplier 1311 and the original signal input to the edge enhancing unit 131 are added by the adder 1313, and the result of addition is output as the output signal of the edge enhancing unit 131.

Given that an input value is S, the output value of the Laplacian filter is Lap(S), the edge detection result supplied from the edge detector 25 is Edge, and the converted value obtained by the LUT converter 1312 is LUT(Edge), an output value S′ of the edge enhancing unit 131 is given by following equation
S′=S+Lap(S)×LUT(Edge)/63.

The combining unit 132 shown in FIG. 4 combines the output signal of the edge enhancing unit 131 and the output signal of the smoothing unit 130 at a given ratio and outputs a combined signal. The combining ratio should be, for example, 1 to 1, i.e., both output signals added and then divided by 2.

In this embodiment, edge enhancement is controlled based on the edge detection result as mentioned above. If the filter that performs a smoothing process and the filter that performs edge enhancement are evaluated as a single combined filter, controlling edge enhancement in the aforementioned manner means controlling the combined filter, so that the combined filter may be so designed as to be equivalent to the one in a case of the smoothing process disabled for a non-edge (edge detection result being 0).

Besides the control of the contents of the edge enhancement based on the edge detection result, the contents of the smoothing process by the smoothing unit 130 may be controlled according to the edge detection result, or the combining ratio may be controlled by the combining unit 132 based on the edge detection result.

The first filtering unit 13 in this embodiment has the parameter setting unit 133 that sets parameters for the individual filters based on the variable magnification ratio supplied from the operation panel 10 (see FIG. 1) to determine the contents of the filtering processes of the smoothing unit 130 and the Laplacian filter 1310.

The parameter setting unit 133 selects a parameter from parameters stored in the parameter memory 26 shown in FIG. 1 according to the variable magnification ratio supplied from the operation panel 10 and sets the selected parameters in the respective filters. Specifically, a plurality of variable magnification ratios (or the range of the variable magnification ratio) and parameters, which should be set in the smoothing unit 130 and the Laplacian filter 1310 when scanning is performed at the respective variable magnification ratios, are stored in the parameter memory 26 beforehand in association with each other, and the parameter setting unit 133 acquires desired parameters from the parameter memory 26 and sets the parameters in the respective filters.

The scan speed (document feeding speed, carriage moving speed, or the like) of the scanner 11 in the sub scan direction changes according to the variable magnification ratio. Therefore, parameters for each variable magnification ratio, which allow the smoothing process and the Laplacian filtering process match with the frequency characteristic corresponding to the scan speed in the sub scan direction, are determined and stored in the parameter memory 26 beforehand. This can ensure the smoothing process and the Laplacian filtering according to the variable magnification ratio.

Although the parameter setting unit 133 sets parameters to determine the contents of the processes to be performed by the smoothing unit 130 and the Laplacian filter 1310 in this embodiment, the parameter setting unit 133 may set a parameter for one of the smoothing unit 130 and the Laplacian filter 1310. Alternatively, the parameter setting unit 133 may be so designed as to be able to set parameters for the edge detecting filters 250 to 253 of the edge detector 25 according to the variable magnification ratio so that edge detection filtering process according to the variable magnification ratio can be executed.

The parameter setting unit 133 sets parameters according to the variable magnification ratio supplied from the operation panel 10 in this embodiment. When the scanner that generates an image signal is changed as in the case where the image processing apparatus does not incorporate a scanner, information on the characteristic of the scanner (device type information) or the like should be acquired and suitable parameters according to the scanner may be set. In this case, parameters that should be set for each of plural scanner types should be prestored in the parameter memory 26.

Even with a built-in scanner 11, the image signal or the like generated by the scanner may change with the passage of time, so that the adequate filtering process that should be performed for the image signal may change. Therefore, information on a time-dependent change or the like of the scanner 11 (e.g., the time elapsed since the date the scanner 11 is used the first time) may be acquired and the parameter setting unit 133 may set adequate parameters based on the information.

Returning to FIG. 1, the image signal subjected to the filtering process in the first filtering unit 13 is output to the main scan unit 14. The main scan unit 14 performs variable magnification on the image signal in the main scan direction according to the variable magnification ratio supplied from the operation panel 10. The main scan unit 14 in this embodiment performs variable magnification in the main scan direction using a cubic function convolution method, so that the variable magnification is combined with variable magnification in the sub scan direction that is executed by the scanner 11. Accordingly, variable magnification based on the variable magnification ratio designated by the user is performed for both the main scan direction and the sub scan direction. This variable magnification for image signals is not restrictive and various variable magnification techniques like the nearest neighbor scheme and linear interpolation, may be used as well.

The image signal magnified in the main scan unit 14 and the compression level information supplied from the operation panel 10 are supplied to the header writing unit 15. The header writing unit 15 writes the compression level, supplied from the operation panel 10, in the header of the image signal and sends the resultant signal to the irreversible compressing unit 16. As the compression level is written as header information, the user can know at what compression rate the image signal has been compressed by referring to the header information at the time of using the image data. The elements at the subsequent stages of the header writing unit 15 (the irreversible compressing unit 16 and the second filtering unit 20) acquire the compression level information by referring to the header information. The information acquisition path is indicated by broken lines in FIG. 1 for the sake of convenience.

The irreversible compressing unit 16 performs irreversible compression like JPEG on the image signal at the compression rate according to the compression level information written in the header. The image signal compressed by the irreversible compressing unit 16 is stored in the memory 17.

The memory 17 stores an image signal compressed by the irreversible compressing unit 16 as described above. The compressed image signal stored in the memory 17 can be read out and supplied to the expanding unit 18 when it is used in the image processing apparatus 100, but can also be read by an external device. That is, an external device (e.g., a PC) can access the memory 17 via an external device interface (LAN interface or the like) so that the external device can read out the compressed image signal stored in the memory 17 and, for example, display the image data to be used.

The expanding unit 18 reads the compressed image signal stored in the memory 17, expands the image signal, and sends the expanded image signal to the color correcting unit 19.

The color correcting unit 19 converts an R′G′B signal after expansion to a C′M′Y′ signal corresponding to the toner colors of the printer unit 24 at the subsequent stage. More specifically, the color correcting unit 19 acquires the C′M′Y′ signal from the R′G′B signal based on following equations
C′=a0+a1×R′+a2×G′+a3×B′
M′=b0+b1×R′+b2×G′+b3×B′
Y′=c0+c1×R′+c2×G′+c3×B′.

In the equations, a0 to a3, b0 to b3, and c0 to c3 are color correction parameters that are guaranteed for achromaticness in such a way that C′=M′=Y′ when R′=G′=B′.

The image signal subjected to the color correction as described above is supplied to the second filtering unit 20. The second filtering unit 20 performs a filtering process on the image signal read from the memory 17 to reduce image degradation originated from the irreversible compression by the irreversible compressing unit 16. More specifically, as shown in FIG. 9, the second filtering unit 20 has an edge enhancing unit 201 and a parameter setting unit 202. The edge enhancing unit 201 performs edge enhancement on the image signal and performs a masking process using an edge enhancing filter of a 3×3 size as exemplified in FIG. 10.

In this embodiment, as described above, the first filtering unit 13 performs edge enhancement, and so does the second filtering unit 20. In this embodiment, the reference area size (3×3) of the edge enhancement executed by the second filtering unit 20 is smaller than the reference area size (5×5) of the edge enhancement executed by the first filtering unit 13. The reason for making smaller the reference area size of the edge enhancement executed by the second filtering unit 20 is because the first filtering unit 13 performs a smoothing process on the image signal, hardly leaving rolling at a large number of dot lines, so that it is less likely that a filter even with a small reference area size would enhance dots, thereby degrading the graininess. Since it is less likely to cause image degradation, the reference area size is made smaller to reduce the processing burden, required hardware resources, or the like.

The parameter setting unit 202 acquires the compression level information written in the header information of an image signal. The parameter setting unit 202 selects a parameter according to the acquired compression level information from those parameters stored in the parameter memory 27 as shown in FIG. 1, and sets the selected parameter in the filter of the edge enhancing unit 201.

Specifically, a plurality of compression levels and those parameters that should be set in the edge enhancing unit 201 at the time compression is performed at the individual compression levels are stored in the parameter memory 27 in association with each other, and the parameter setting unit 202 acquires a desired parameter from the parameter memory 27 and sets the parameter.

If the compression levels of images differ from one another, the degrees of degradation or the like of compressed images differ from one another, so that processing should be performed according to the compression level in order to adequately decrease compression-oriented image degradation. When the compression level is high, for example, drop-off of the high-frequency component becomes large, making it preferable to execute stronger edge enhancement to restore dropped-off information as much as possible in order to reduce image degradation. In such a case, therefore, it is preferable to set parameters in such a way as to execute stronger edge enhancement.

Accordingly, parameters that ensure suitable edge enhancement to reduce image degradation are stored in the parameter memory 27 in this embodiment in association with various compression levels. This allows the parameter setting unit 202 to set parameters in such a way as to perform adequate processing according to the compression level.

Although the second filtering unit 20 performs edge enhancement in this embodiment, it may be designed to perform a smoothing process by use of a smoothing filter in addition to edge enhancement. With such configuration as to perform a smoothing process, execution of the smoothing process can reduce the degree of image degradation even for an image signal that has been compressed at a high compression rate to suffer block deformation at the flat portion of the image. When the second filtering unit 20 performs a smoothing process, it is preferable that, like the first filtering unit 13, the second filtering unit 20 be an adaptive type filter that performs filtering based on the edge detection result.

The image signal subjected to the filtering process in the second filtering unit 20 with the above configuration is output to the UCR/black generating unit 21. The UCR/black generating unit 21 performs a black generating process to generate a K signal from the C′M′Y′ signal supplied from the second filtering unit 20 and performs under color removal (UCR) to reduce the amount according to the generated K signal from the C′M′Y′ signal. In this embodiment, the K signal and the CMY signal are generated based on following equations
K=Min(C′,M′,Y′)×α
C=C′−K
M=M′−K
Y=Y′−K.

In the above equations, α is a given value (a predetermined value or the like) in the range of 0≦α≦1, and when α=1, UCR becomes 100% at which a black component becomes a K signal 100%. Black generation may be performed using LUT conversion as well as through the computations, and various known black generating processes can be used.

As described above, the image signal (CMYK signal) subjected to the black generating process in the UCR/black generating unit 21 is supplied to the y correcting unit 22. The y correcting unit 22 performs a density converting process for matching with the density characteristic of the printer unit 24 using a density conversion table and sends the converted image signal to the pseudo intermediate processor 23. The pseudo intermediate processor 23 performs a pseudo intermediate process like dithering or error diffusion on the image signal and sends the processed image signal to the printer unit 24. The printer unit 24 outputs an image corresponding to the image signal, subjected to various types of image processing, from the pseudo intermediate processor 23 onto a sheet of paper or the like.

According to this embodiment, as described above, the first filtering unit 13 performs a filtering process on an image signal input from the scanner 11 to reduce image degradation originated from optical scanning of a document before the irreversible compressing unit 16 performs irreversible compression on the image signal, and the second filtering unit 20 performs a filtering process on an expanded image signal read from the memory 17 to reduce image degradation originated from the irreversible compression.

When an image based on an image signal subjected to the filtering process in the second filtering unit 20 is output, therefore, it is possible to acquire the image with lower degradation originated from optical scanning of a document and lower degradation originated from image compression. Even when a compressed image stored in the memory 17 is used, for example, displayed, by an external device such as a PC, other than the image processing apparatus 100, since the image signal stored in the memory 17 has been subjected to a filtering process in the first filtering unit 13, it is possible to acquire an image with lower degradation originated from optical scanning of a document. Accordingly, even when an image scanned by the scanner 11 includes characters or the like, the possibility that an image to be displayed is too degraded to make the characters or the like unidentifiable can be reduced.

The image processing apparatus 100 of this embodiment can not only acquire an image with suppressed degradation at the time of using the image on the local image processing apparatus but can also reduce the degree of image degradation even when the image signal input to the-image processing apparatus 100 is used by an external device.

In this embodiment, edge enhancement is performed not only on the image signal before image compression in the processing of the first filtering unit 13 but also on the image signal read from the memory 17 and expanded. It is therefore possible to individually set the contents of the edge enhancement. For example, while the setting is performed in such a way that edge enhancement that is suitable for viewing the image on the display of a PC is executed by the first filtering unit 13, the setting is performed in such a way that edge enhancement that is suitable for printout by the printer unit 24 is executed by the second filtering unit 20.

Since the contents of the edge enhancement by the first filtering unit 13 and the contents of the edge enhancement by the second filtering unit 20 can be set individually, an increase in image degradation originated from irreversible compression at the subsequent stage can be suppressed by making the degree of the edge enhancement by the first filtering unit 13 smaller than the degree of the edge enhancement by the edge enhancing unit 201 of the second filtering unit 20.

As the first filtering unit 13 (and the second filtering unit 20) performs an adaptive filtering process based on the edge detection result, it is possible to perform edge enhancement on characters while not performing edge enhancement at a large number of dot lines (including the most ordinary dot lines near 150 lines and 200 lines). This can ensure acquisition of an image with the adequate sharpness while suppressing image degradation originated from irreversible compression of a pattern portion.

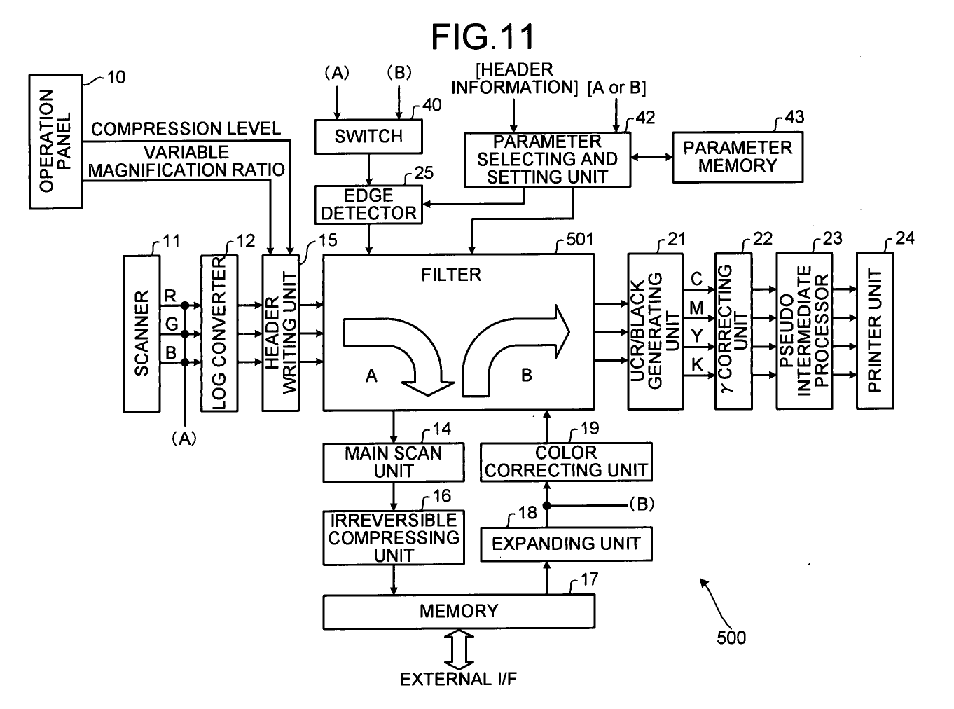

FIG. 11 is a block diagram of an image processing apparatus according to one embodiment of the present invention. In this embodiment, like elements in another embodiment are designated by like reference numerals, and the description thereof is omitted.

An image processing apparatus 500 according to one embodiment differs from the image processing apparatus of another embodiment in the following respects: there are provided a filtering unit 501 in place of the first filtering unit 13 and the second filtering unit 20 (see FIG. 1), a switch 40, a parameter selecting and setting unit 42, and a parameter memory 43 in place of the parameter memories 26 and 27; and the header writing unit 15 is located at the subsequent stage of the LOG converter 12.

The image processing apparatus 500 of one embodiment supplies an image signal from the scanner 11 to the header writing unit 15 via the LOG converter 12. The header writing unit 15 is supplied with information, such as the variable magnification ratio and compression level, from the operation panel 10 in addition to the image signal. The header writing unit 15 writes information, such as the variable magnification ratio and compression level, in the header and then sends the resultant image signal to the filtering unit 501.

Like the first filtering unit 13 in a previously-described embodiment (see FIGS. 4 and 5), the filtering unit 501 in another embodiment has a smoothing filter and an edge enhancing filter each of which performs a filtering process according to the parameter set by the parameter selecting and setting unit 42.

As mentioned above, the filtering unit 501 in one embodiment is supplied with an image signal before irreversible compression from the header writing unit 15. When the image signal is supplied from the header writing unit 15, a filtering process according to the parameters set by the parameter selecting and setting unit 42 is performed on the image signal and the processed image signal is supplied to the main scan unit 14. In the following description, such a flow of the image signal is called “path A.”

An image signal that is temporarily irreversibly compressed and then expanded is supplied to the filtering unit 501 from the color correcting unit 19. When receiving the image signal from the color correcting unit 19, the filtering unit 501 performs a filtering process on the image signal according to the parameters set by the parameter selecting and setting unit 42 and supplies the processed image signal to the UCR/black generating unit 21. In the following description, such a flow of the image signal is called “path B.”

In one embodiment, the image signal generated by the scanner 11 is supplied to the LOG converter 12 and the switch 40. The switch 40 is supplied with the image signal read from the memory 17 and expanded by the expanding unit 18 in addition to the image signal from the scanner 11.

When the filtering unit 501 performs a filtering process on the image signal that flows along the path A, the switch 40 sends the image signal supplied from the scanner 11 to the edge detector 25. When the filtering unit 501 performs a filtering process on the image signal that flows along the path B, on the other hand, the switch 40 sends the image signal supplied from the expanding unit 18 to the edge detector 25.

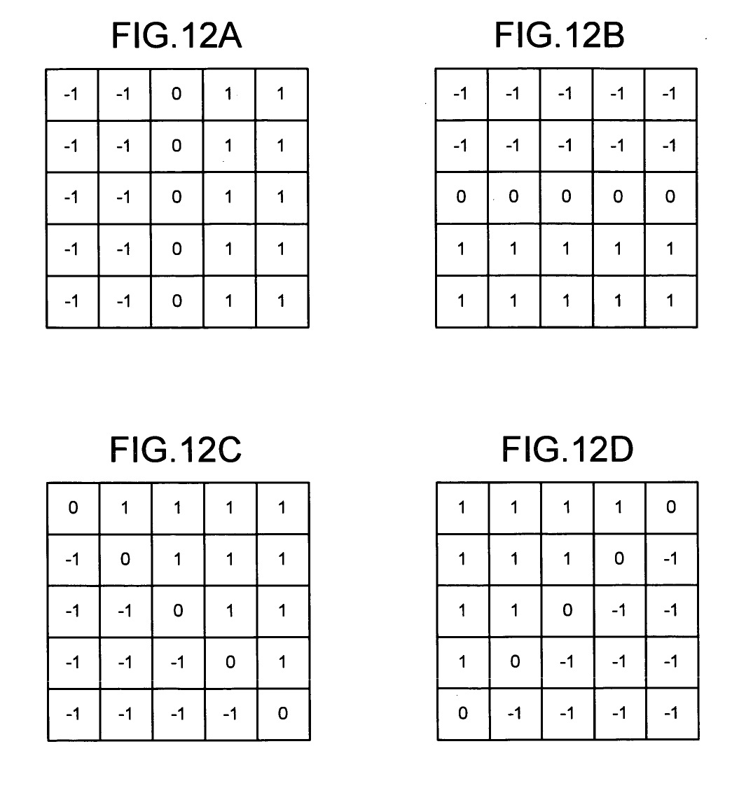

Accordingly, the edge detector 25 sends the result of edge detection performed on the image signal before compression supplied from the scanner 11 to the filtering unit 501 when the filtering unit 501 performs the filtering process on the image signal that flows along the path A. The edge detector 25 sends the result of edge detection performed on the image signal supplied from the expanding unit 18 to the filtering unit 501 when the filtering unit 501 performs the filtering process on the image signal that flows along the path B. Accordingly, the filtering unit 501 serves as an adaptive filter based on the edge detection result supplied from the edge detector 25 as performed in one embodiment. FIGS. 12A to 12D depict examples of four edge detecting filters (see FIG. 2) included in the edge detector 25. As shown in the diagram, edge detection can be performed by using 5×5 filters.

At the time the filtering unit 501 performs a filtering process on an image signal, the parameter selecting and setting unit 42 sets parameters for the smoothing filter and edge enhancing filter of the filtering unit 501 to determine the contents of the filtering process that is performed by the filtering unit 501.

More specifically, the parameter selecting and setting unit 42 selects and sets parameters as follows. The parameter selecting and setting unit 42 is supplied with path information indicating along which one of the paths A and B the header information written by the header writing unit 15 and the image signal to be processed by the filtering unit 501 flow.

Based on the variable magnification ratio and compression level information written in the header information, the parameter selecting and setting unit 42 selects parameters that are to be set in the smoothing filter and the edge enhancing filter (Laplacian filter and LUT to be referred to by the LUT converter) from those stored in the parameter memory 43.

Parameters to be set in the smoothing filter and the edge enhancing filter are stored in the parameter memory 43 for each of the path A and the path B. In this example, parameters similar to those stored in the parameter memory 26 (see FIG. 1) in one embodiment are stored as the parameters for the path A, and parameters similar to those stored in the parameter memory 27 (see FIG. 1) are stored as the parameters for the path B.

Parameters to be set in association with a plurality of variable magnification ratios are stored as the parameters for the path A, and parameters to be set in association with a plurality of compression levels are stored as the parameters for the path B. That is, parameters that ensure a suitable filtering process on an image signal before compression that flows along the path A according to the variable magnification ratio of that image signal, and parameters that ensure a suitable filtering process on an image signal that flows along the path B according to the compression level of that image signal are stored in the parameter memory 43 as per one embodiment.

When the path information to be supplied indicates the path A, the parameter selecting and setting unit 42 selects parameters corresponding to the supplied variable magnification ratio from those parameters for the path A stored in the parameter memory 43 and sets the selected parameters in the smoothing filter and the edge enhancing filter (Laplacian filter and LUT to be referred to by the LUT converter). When the path information to be supplied indicates the path B, the parameter selecting and setting unit 42 selects parameters corresponding to the supplied compression level from those parameters for the path B stored in the parameter memory 43 and sets the selected parameters in the smoothing filter and the edge enhancing filter (Laplacian filter and LUT to be referred to by the LUT converter).

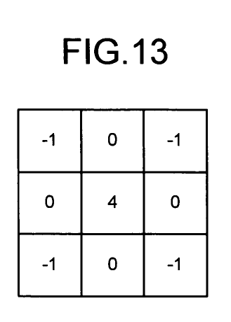

FIG. 13 depicts an example of a Laplacian filter (see FIG. 6) in the edge enhancing unit at the time the filtering unit 501 performs a filtering process on an image signal before compression, which flows along the path A, according to the setting by the parameter selecting and setting unit 42. As shown in the diagram, a filter with a size of 3×3 can be used as the Laplacian filter. In the case where 3×3 filtering process is performed when the filtering unit 501 has a defined filter size of 5×5, the parameter selecting and setting unit 42 has only to set parameters in such a way that the filter serves as a 5×5 filter having a coefficient of 0 placed around the 3×3 size.

The filtering unit 501 with the configuration described above can perform a filtering process similar to that of the first filtering unit 13 in one embodiment with respect to an image signal before compression that flows along the path A, and can perform a filtering process similar to that of the second filtering unit 20 in one embodiment with respect to an image signal that flows along the path B.

Like the image processing apparatus 100 of a previously-described embodiment, therefore, the image processing apparatus 500 of another embodiment can perform a filtering process to reduce image degradation originated from image signal generation performed by optical scanning of a document with respect to the image signal before compression that is supplied from the scanner 11, and a filtering process to reduce image degradation originated from irreversible compression with respect to the expanded image signal read from the memory 17.

The execution of the filtering processes not only provides an image with suppressed image degradation when the image signal generated by the scanner 11 is used (printed or the like) by the local image processing apparatus, but also reduces the degree of image degradation when the image signal input to the image processing apparatus 100 from the scanner 11 or the like is used by an external device.

As the filtering unit 501 in a previously-described embodiment achieves functions equivalent to the functions of the first filtering unit 13 and the second filtering unit 20 in a previously-described embodiment, one embodiment does not increase the hardware resources.

A program, which allows a computer to execute the first filtering process before image compression and the second filtering process after image expansion that are performed in one embodiment, may be supplied to users via a communication line such as the Internet, or may be supplied to users in the form of a computer readable recording medium, such as a compact disc-read only memory (CD-ROM), having the program recorded thereon.

According to one embodiment of the present invention, an image with suppressed image degradation can be acquired in both of the case where the image signal compressed and stored in the storage unit is expanded and used, and the case where the compressed image signal stored in the storage unit is read and used by an external device.

According to one embodiment of the present invention, the contents of edge enhancement on an image signal before compression and an image signal after compression can be set individually.

According to one embodiment of the present invention, as the smoothing process is already performed in the edge enhancement on the expanded image signal, it is less likely for image degradation to occur even when the reference area size is made smaller. Furthermore, reducing the reference area size brings about an effect of reducing the processing burden.

According to one embodiment of the present invention, a suitable filtering process according to the edge detection result can be executed, thereby reducing image degradation.

According to one embodiment of the present invention, a suitable filtering process according to the variable magnification ratio can be executed, thereby reducing image degradation.

According to one embodiment of the present invention, a suitable filtering process according to the compression level can be executed, resulting in a reduction in image degradation.

According to one embodiment of the present invention, the filtering process on an image signal before compression and the filtering process on an image signal that is temporarily compressed and then expanded can be performed by the same filtering unit. This simplifies the hardware configuration.

Although the invention has been described with respect to a specific embodiment for a complete and clear disclosure, the appended claims are not to be thus limited but are to be construed as embodying all modifications and alternative constructions that may occur to one skilled in the art that fairly fall within the basic teaching herein set forth.

1. An image processing apparatus comprising;
an input unit to input an image signal created by optically scanning a document;
a first filtering unit to perform a first filtering process on the image signal input by the input unit to reduce degradation of image quality caused by optical scanning of the document;
a compressing unit to irreversibly compress the image signal filtered by the first filtering unit;
a storage unit to store the image signal compressed by the compressing unit;
an expanding unit to expand compressed image signal stored in the storage unit; and
a second filtering unit to perform a second filtering process on the image signal expanded by the expanding unit to reduce degradation image quality caused by compression of the image signal.

2. The image processing apparatus according to claim 1, wherein the first filtering process and the second filtering process includes at least an edge enhancing process.

3. The image processing apparatus according to claim 2, wherein
the first filtering process includes a smoothing process, and
the second filtering process includes the edge enhancing process in a reference area size smaller than that of the edge enhancing process by the first filtering unit.

4. The image processing apparatus according to claim 1, further comprising an edge detector to perform edge detection on the image signal input by the input unit, wherein
at least one of the first filtering unit and the second filtering unit performs a filtering process determined based on a result of detection by the edge detector.

5. The image processing apparatus according to claim 1, wherein the first filtering unit performs a filtering process determined based on a magnification ratio of the image signal input by the input unit.

6. The image processing apparatus according to claim 1, wherein the second filtering unit performs a filtering process determined based on a level of compression of the image signal.

7. An image processing apparatus comprising;
an input unit to input an image signal created by optically scanning a document;
a filtering unit to perform a filtering process on the image signal;
a compressing unit to irreversibly compress the image signal input by the input unit;
a storage unit to store the image signal compressed by the compressing unit;
an expanding unit to expand the image signal stored in the storage unit; and
a determining unit to determine contents of the filtering process, wherein
before compression of the image signal, the filtering process reduces degradation of image quality caused by optical scanning of the document, and
after expanding the compressed image signal, the filtering process reduces degradation of image quality caused by compression of the image signal.

8. The image processing apparatus according to claim 7, wherein the determining unit determines at least an edge enhancing process on both the image signal before the compression and the image signal after the expansion.

9. The image processing apparatus according to claim 8, wherein the determining unit determines a smoothing process on the image signal before the compression, the edge enhancing process on the image signal after the expansion in a reference area size smaller than that of the edge enhancing process performed on the image signal before the compression.

10. The image processing apparatus according to claim 7, further comprising an edge detector to perform edge detection on the image signal input by the input unit, wherein
the determining unit determines the filtering process on at least one of the image signal before the compression and the image signal after the expansion based on a result of detection by the edge detector.

11. The image processing apparatus according to claim 7, wherein the determining unit determines the filtering process on the image signal before the compression based on a magnification ratio of the image signal input by the input unit.

12. The image processing apparatus according to claim 7, wherein the determining unit determines the filtering process on the image signal after the expansion based on a level of the compression of the image signal.

13. An image processing method comprising:
inputting an image signal created by optically scanning a document;
performing a first filtering process on the image signal input by the input unit to reduce degradation of image quality caused by optical scanning of the document;
compressing the image signal filtered by the first filtering unit;
storing the image signal compressed by the compressing unit;
expanding compressed image signal stored in the storage unit; and
performing a second filtering process on the image signal expanded by the expanding unit to reduce degradation image quality caused by compression of the image signal.

14. The image processing method according to claim 13, wherein, the performing a first filtering process and the performing a second filtering process includes at least performing an edge enhancing process.

15. An article of manufacture comprising one or more recordable media having instructions stored thereon, which, when executed by a computer, cause the computer to:
input an image signal created by optically scanning a document;
perform a first filtering process on the image signal input by the input unit to reduce degradation of image quality caused by optical scanning of the document;
compress the image signal filtered by the first filtering unit;
store the image signal compressed by the compressing unit;
expand compressed image signal stored in the storage unit; and
perform a second filtering process on the image signal expanded by the expanding unit to reduce degradation image quality caused by compression of the image signal.
